(19) United States
(12) Patent Application Publication
(10) Pub. No.: US 2023/0389369 A1
(43) Pub. Date: Nov. 30, 2023

(54) DISPLAY DEVICE

(71) Applicant: Japan Display Inc., Tokyo (JP)

(72) Inventor: Takahiro USHIKUBO, Tokyo (JP)

(73) Assignee: Japan Display Inc., Tokyo (JP)

(21) Appl. No.: 18/448,983

(22) Filed: Aug. 14, 2023

Related U.S. Application Data
(63) Continuation of application No. PCT/JP2022/005046, filed on Feb. 9, 2022.

(30) Foreign Application Priority Data
Feb. 25, 2021 (JP) 2021-029126

(51) Int. Cl. H10K 59/124

(52) U.S. Cl. CPC H10K 59/124; H10K 59/35

(57) ABSTRACT

A display device includes a first pixel electrode, a second pixel electrode arranged in a first direction and spaced apart from the first pixel electrode, an insulating layer having a first opening exposing at least a portion of a top surface of the first pixel electrode and a second opening exposing at least a portion of a top surface of the second pixel electrode, a first common layer arranged on the first pixel electrode, the second pixel electrode, and the insulating layer, a first light-emitting layer arranged on the first common layer, and overlapping the first pixel electrode, a second light-emitting layer arranged on the first common layer, overlapping the second pixel electrode, and having a lower emission starting voltage than that of the first light-emitting layer, and a counter electrode arranged on the first light-emitting layer and the second light-emitting layer.

### CROSS-REFERENCE TO RELATED APPLICATIONS

This application is a Continuation of International Patent Application No. PCT/JP2022/005046, filed on Feb. 9, 2022, which claims the benefit of priority to Japanese Patent Application No. 2021-029126, filed on Feb. 25, 2021, the entire contents of each are incorporated herein by reference.

### FIELD

An embodiment of the present invention relates to a display device and a manufacturing method thereof.

### BACKGROUND

Conventionally, an organic EL display device (Organic Electroluminescence Display) using an organic electroluminescent material (organic EL material) as a light-emitting element (organic EL element) of a display unit has been known as a display device. In recent years, there has been an increasing demand for higher definition in the organic EL display device (Japanese laid-open patent publication No. 2011-9169).

As the resolution of the EL display device advances, a distance between the pixels becomes closer, and therefore, the effect of a leakage current flowing between adjacent pixels (hereinafter, also referred to as “leakage current in the transverse direction”) is actualized. In the EL display device, the leakage current in the transverse direction may cause the adjacent pixels to emit light, thereby deteriorating the quality of the EL display device.

### SUMMARY

A display device according to an embodiment of the present invention includes a first pixel electrode, a second pixel electrode arranged in a first direction and spaced apart from the first pixel electrode, an insulating layer having a first opening exposing at least a portion of a top surface of the first pixel electrode and a second opening exposing at least a portion of a top surface of the second pixel electrode, a first common layer arranged on the first pixel electrode, the second pixel electrode, and the insulating layer, a first light-emitting layer arranged on the first common layer, and overlapping the first pixel electrode, a second light-emitting layer arranged on the first common layer, and overlapping the second pixel electrode, and having a lower emission starting voltage than that of the first light-emitting layer; and a counter electrode arranged on the first light-emitting layer and the second light-emitting layer, wherein the first light-emitting layer is spread over the insulating layer and an edge the first light-emitting layer is arranged on an inclined surface of the second opening in the insulating layer, and the second light-emitting layer includes a region overlapping the first light-emitting layer.

### BRIEF DESCRIPTION OF DRAWINGS

FIG. 1 is a schematic diagram when a display device according to an embodiment of the present invention is in a plan view.

FIG. 2 is an enlarged view of a pixel layout when a display device is in a plan view.

FIG. 3 is a cross-sectional view when a display device shown in FIG. 2 is cut along a line A1-A2.

FIG. 4 is an enlarged view of part of the cross-sectional view shown in FIG. 3.

FIG. 5 is a cross-sectional view illustrating a manufacturing method of a display device according to an embodiment of the present invention.

FIG. 6 is a cross-sectional view illustrating a manufacturing method of a display device according to an embodiment of the present invention.

FIG. 7 is a cross-sectional view illustrating a manufacturing method of a display device according to an embodiment of the present invention.

FIG. 8 is a pixel layout diagram when a display device according to an embodiment of the present invention is in a plan view.

FIG. 9 is a cross-sectional view when a display device shown in FIG. 8 is cut along a line B1-B2.

FIG. 10 is an enlarged view of a pixel layout when a display device is in a plan view.

FIG. 11 is a cross-sectional view when a display device shown in FIG. 10 is cut along a line C1-C2.

FIG. 12 is an enlarged view of a pixel layout when a display device is in a plan view.

FIG. 13 is a cross-sectional view when a display device shown in FIG. 12 is cut along a line D1-D2.

FIG. 14 is an enlarged view of a pixel layout when a display device is in a plan view.

FIG. 15 is an enlarged view of a pixel layout when a display device is in a plan view.

FIG. 16 is a cross-sectional view when a display device shown in FIG. 14 is cut along a line E1-E2.

FIG. 17 is a cross-sectional view of a display device according to an embodiment of the present invention.

FIG. 18 is an enlarged view of a pixel layout when a conventional display region is in a plan view.

FIG. 19 is a cross-sectional view when a display region shown in FIG. 18 is cut along a line F1-F2.

FIG. 20 is an enlarged view of part of the cross-sectional view shown in FIG. 19.

FIG. 21 is a cross-sectional view when a display region shown in FIG. 18 is cut along a line F1-F2.

FIG. 22 is an enlarged view of part of the cross-sectional view shown in FIG. 21.

### DESCRIPTION OF EMBODIMENTS

Hereinafter, embodiments of the present invention will be described with reference to the drawings and the like. However, the present invention can be implemented in various aspects without departing from the gist thereof, and is not to be construed as being limited to the description of the embodiments exemplified below. In addition, in order to make the description clearer with respect to the drawings, the width, thickness, shape, and the like of each part may be schematically represented in comparison with actual embodiments, but the schematic drawings are merely examples, and do not limit the interpretation of the present invention. Further, in the present specification and the drawings, the same or similar elements as those described with respect to the above-described drawings are denoted by the same reference signs, and redundant description may be omitted.

In the present invention, in the case where a single film is processed to form a plurality of films, the plurality of films may have different functions and roles. However, the plurality of films is derived from a film formed as the same layer in the same process and has the same layer structure and material. Therefore, the plurality of films is defined as being present in the same layer.

In addition, in the present specification, expressions such as “on” and “under” in describing the drawings represent relative positional relationships between a structure of interest and another structure. In the present specification, in a side view, a direction from an insulating surface to a light-emitting element, which will be described later, is defined as “on”, and a reverse direction thereof is defined as “under”. In the present specification and claims, the expression “on” in describing the manner of arranging another structure on a certain structure shall include both arranging another structure directly above a certain structure and arranging another structure above a certain structure via yet another structure, unless otherwise specified.

### First Embodiment

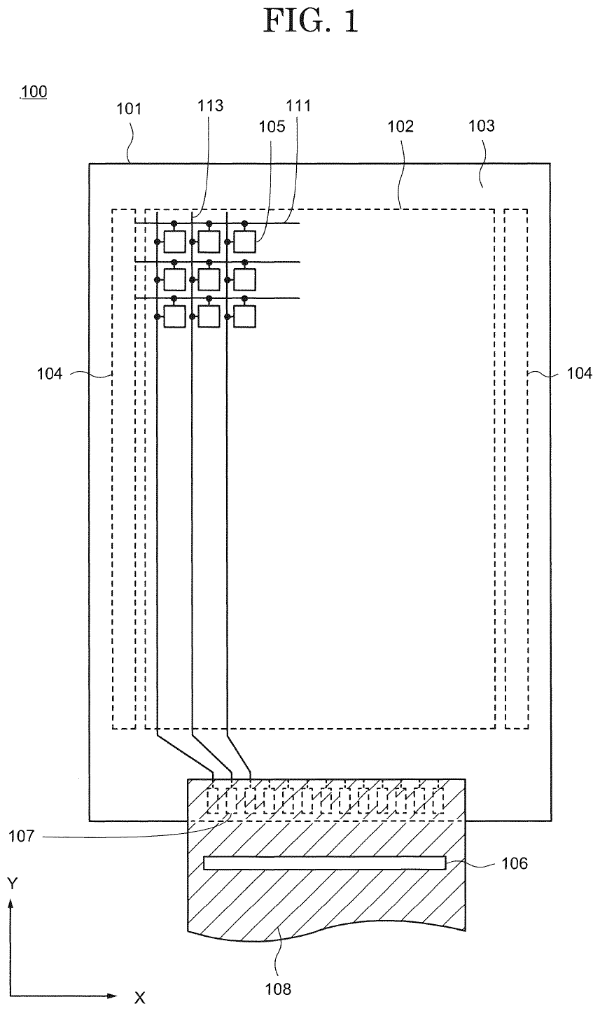

A display device according to an embodiment of the present invention will be described with reference to FIG. 1 to FIG. 17.

FIG. 1 is a schematic diagram showing a configuration of a display device 100 according to an embodiment of the present invention, and shows a schematic configuration when the display device 100 is in a plan view. In the present specification, a state in which the display device 100 is viewed from a direction perpendicular to a screen (display region) is referred to as a “plan view”.

As shown in FIG. 1, the display device 100 includes a display region 102 formed on an insulating surface, a scanning line driving circuit 104, a driver IC 106, and a terminal portion in which a plurality of terminals 107 is arranged. A light-emitting element having an organic layer composed of organic material is arranged in the display region 102. In addition, a peripheral region 103 surrounds the display region 102. The driver IC 106 functions as a control unit that provides a signal to the scanning line driving circuit 104 and a data line driving circuit. The data line driving circuit may be arranged with a sampling switch or the like on a substrate 101 separately from the driver IC 106. In addition, the driver IC 106 is arranged on a flexible printed circuit (FPC) 108, but may be arranged on the substrate 101. The flexible printed circuit 108 is connected to the plurality of terminals 107 arranged in the peripheral region 103.

In this case, the insulating surface is a surface of the substrate 101. The substrate 101 supports each layer, such as an insulating layer and a conductive layer, arranged on its surface. In addition, the substrate 101 may be made of insulating material, may have an insulating surface, or an insulating film may be separately formed on the substrate 101 to form an insulating surface. The material of the substrate 101 and the material for forming the insulating film are not particularly limited as long as the insulating surface can be obtained.

In the display region 102 shown in FIG. 1, a plurality of pixels 105 is arranged in a matrix in a direction X and a direction Y. In the present specification and the like, a pixel refers to the smallest unit that enables the display of a desired color in the display region 102. Each pixel 105 has a pixel circuit and a light-emitting element electrically connected to the pixel circuit. The light-emitting element includes a pixel electrode, an organic layer (light-emitting unit) including a light-emitting layer stacked on the pixel electrode, and a counter electrode. The light-emitting elements included in the pixel 105 emit different colors. For example, the pixel 105 emits a color of either a red light-emitting element, green light-emitting element, or blue light-emitting element. In addition, the color emitted by the light-emitting element is not limited to the above, and may be at least one color or more. In the present specification and the like, a component included in the red light-emitting element is indicated by R, a component included in the green light-emitting element is indicated by G, and a component included in the blue light-emitting element is indicated by B. In addition, the emission peak wavelength of the blue light-emitting element is 460 nm or more and 500 nm or less. The emission peak wavelength of the red light-emitting element is 610 nm or more and 780 nm or less. The emission peak wavelength of the green light-emitting element is 500 nm or more and 570 nm or less.

Each pixel 105 is electrically connected to a scanning line 111 and a data line 113. Although not shown, the pixel 105 is electrically connected to a power supply line. The scanning line 111 extends along the direction X and is electrically connected to the scanning line driving circuit 104. The data line 113 extends along the direction Y and is electrically connected to the driver IC 106. In addition, the driver IC 106 outputs a scanning signal to the scanning line 111 via the scanning line driving circuit 104. The driver IC 106 outputs a data signal corresponding to image data to the data line 113. Since the scanning signal and the data signal are input to the pixel circuit included in each pixel 105, a screen display corresponding to the image data can be performed. The pixel circuit is composed of a plurality of transistors. Typically, a thin film transistor (Thin Film Transistor: TFT) can be used as the transistor. However, the present invention is not limited to the thin film transistor, and any element having a current control function may be used.

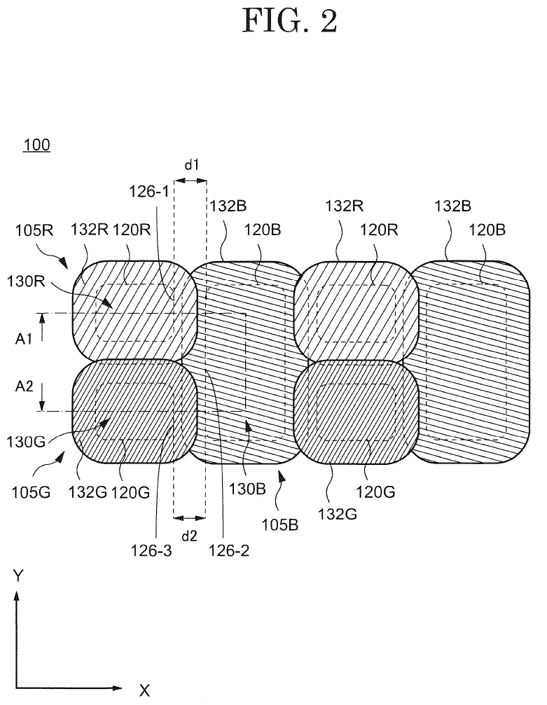

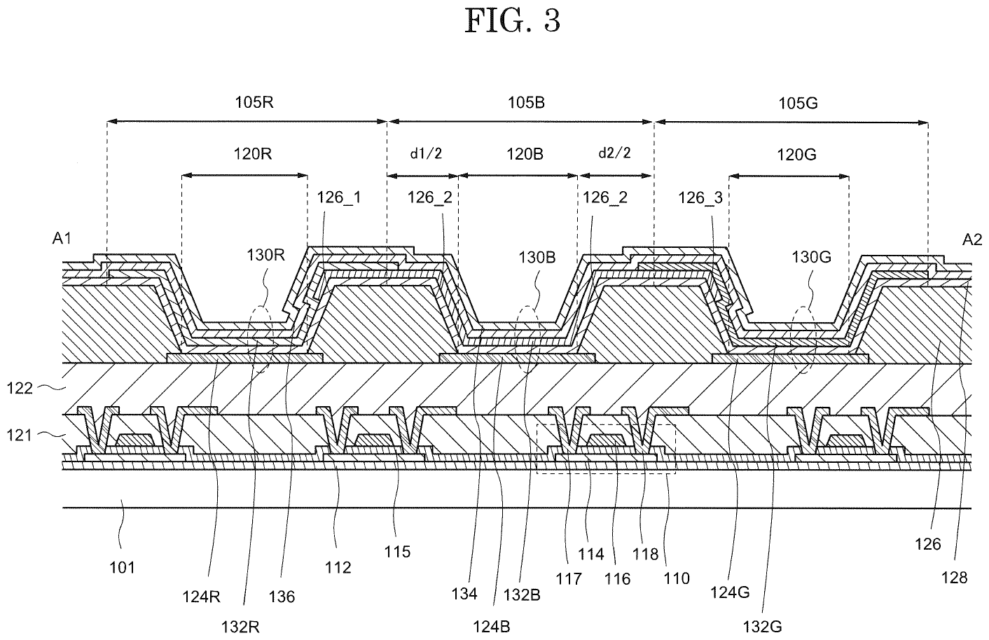

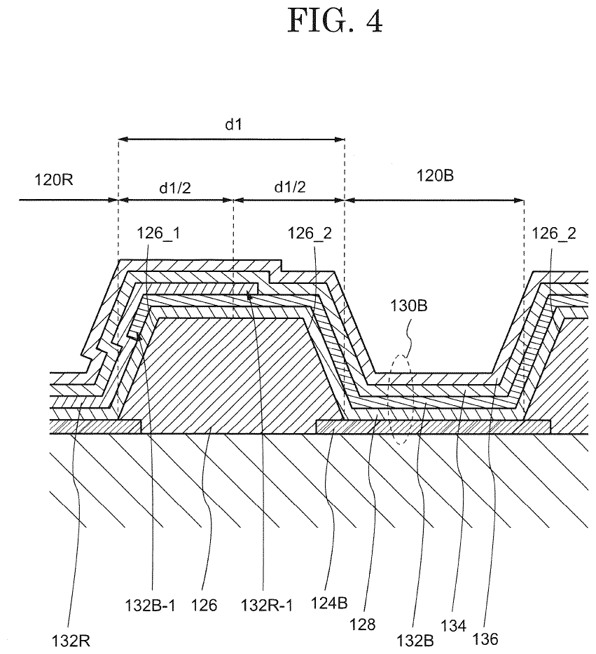

FIG. 2 is an enlarged view of a pixel layout when the display device 100 is in a plan view, and FIG. 3 is a cross-sectional view when the pixel layout shown in FIG. 2 is cut along a line A1-A2. FIG. 4 is an enlarged view of part of the cross-sectional view shown in FIG. 3. In the present embodiment, a configuration of a top-emission display device will be described.

FIG. 2 shows a region where pixels 105R, 105G, and 105B are arranged. The pixel 105R and the pixel 105B are arranged side by side in the direction X. The pixel 105G and the pixel 105B are arranged side by side in the direction X. The pixel 105R and the pixel 105G are arranged side by side in the direction Y. In FIG. 2, a region indicated by a solid line is a region where light-emitting layers 132R, 132G, and 132B are arranged. In addition, a region surrounded by a dotted line is a region where openings 120R, 120G, and 120B are arranged in an insulating layer. The insulating layer is also referred to as a barrier or bank. The openings 120R, 120G, and 120B arranged in the insulating layer correspond to the light-emitting region when light-emitting elements 130R, 130G, and 130B actually emit light. In addition, the light-emitting elements 130R, 130G, and 130B are referred to as the light-emitting element 130 when they are not distinguished from each other. The same applies to each component of the light-emitting elements 130R, 130G, and 130B.

FIG. 3 shows a cross-sectional view of the pixels 105R, 105G, and 105B. A plurality of transistors 110 is arranged on the substrate 101 via an insulating film 112. The plurality of transistors 110 constitutes the pixel circuit. The transistor 110 is composed of at least a semiconductor layer 114, a gate insulating film 115, and a gate electrode 116. An interlayer insulating film 121 is arranged on the transistor 110. Source or drain electrodes 117 and 118 are arranged on the interlayer insulating film 121. Each of the source or drain electrodes 117 and 118 is connected to the semiconductor layer 114 via a contact hole arranged in the interlayer insulating film 121. An insulating film 122 is arranged on the interlayer insulating film 121. The insulating film 122 can relieve unevenness caused by the transistor 110 and the source or drain electrodes 117 and 118. The plurality of transistors 110 arranged on the substrate 101 and the interlayer insulating film 121 and the insulating film 122 arranged on the transistor 110 are formed by known materials and methods. In addition, in FIG. 4 and subsequent figures, illustrations of configurations of the pixel circuit arranged below the insulating film 122 are omitted.

On the insulating film 122, the light-emitting element 130R is arranged in the pixel 105R, the light-emitting element 130G is arranged in the pixel 105G, and the light-emitting element 130B is arranged in the pixel 105B. The light-emitting element 130R has at least a pixel electrode 124R, the light-emitting layer 132R, and a counter electrode 136. The light-emitting element 130G has at least a pixel electrode 124G, the light-emitting layer 132G, and the counter electrode 136. The light-emitting element 130B has at least a pixel electrode 124B, the light-emitting layer 132B, and the counter electrode 136. A common layer 128 is arranged between the pixel electrodes 124R, 124G, and 124B and the light-emitting layers 132R, 132G, and 132B. A common layer 134 is arranged between the light-emitting layers 132R, 132G, and 132B and the counter electrode 136. The common layers 128 and 134 are arranged in common over the light-emitting elements 130R, 130G, and 130B. In FIG. 3, the pixel electrodes 124R, 124G, and 124B are anodes and the counter electrode 136 is a cathode. The common layer 128 includes at least one of a hole transport layer and a hole injection layer, and the common layer 134 includes at least one of an electron transport layer and an electron injection layer. Although not shown in FIG. 3, the pixel electrodes 124R, 124G, and 124B are electrically connected to the transistor 110 included in the pixel circuit.

In the present embodiment, the light-emitting layer 132R overlaps a first end portion of the light-emitting layer 132B when the display device 100 is viewed in a cross section. In addition, the light-emitting layer 132G overlaps a second end portion of the light-emitting layer 132B. In this case, the first end portion of the light-emitting layer 132B is arranged so as to be close to the opening 120R of the light-emitting element 130R. In addition, the second end portion of the light-emitting layer 132B is arranged so as to be close to the opening 120G of the light-emitting element 130G. Specifically, the first end portion of the light-emitting layer 132B is arranged on an inclined surface 126-1 of the opening 120R of an insulating layer 126. In addition, the second end portion of the light-emitting layer 132B is arranged on an inclined surface 126-3 of the opening 120G of the insulating layer 126. In the present specification and the like, the end portion of the light-emitting layer means an outer edge of the light-emitting layer when the display device 100 is in a plan view. In the present specification and the like, the display device 100 is cut along a plane or curved surface that intersects the insulating surface, and a state in which the cut surface is viewed from a direction parallel to the screen is referred to as a “cross-sectional view”.

As the definition of EL display device advances, a distance between the pixels becomes closer, and therefore, the effect of a leakage current in the transverse direction flowing between adjacent pixels increases. In the EL display device, the leakage current in the transverse direction may cause the light-emitting layers of the adjacent pixels to emit light, thereby deteriorating the quality of the EL display device.

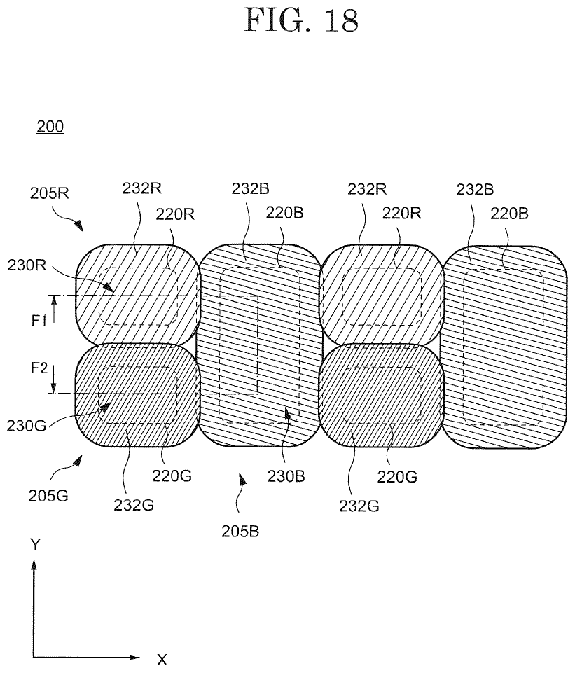

A mechanism in which the light-emitting layer emits light in an unintended region in adjacent pixels due to the leakage current in the transverse direction in the EL display device will be described with reference to FIG. 18 to FIG. 22. In FIG. 18 to FIG. 22, configurations of the pixel circuit arranged below an insulating film 222 are omitted.

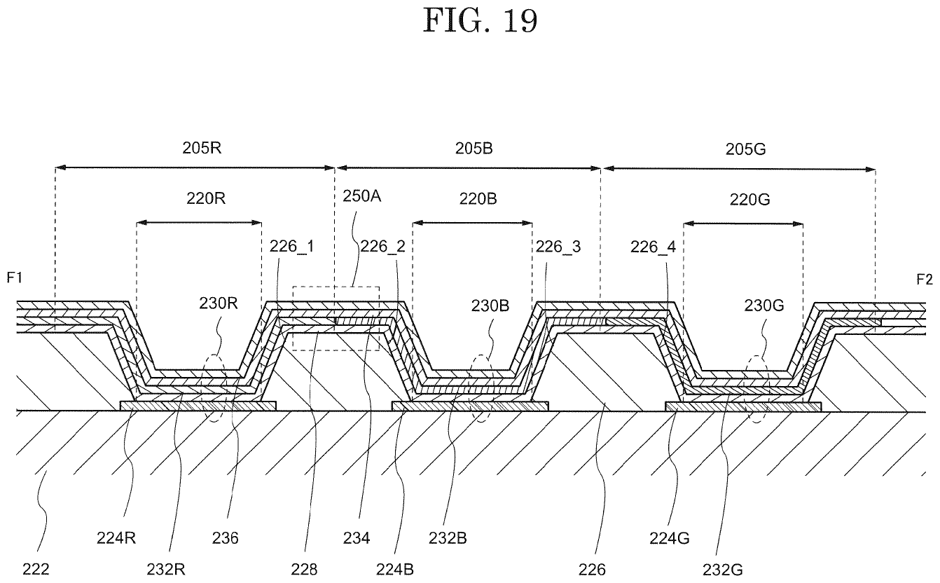

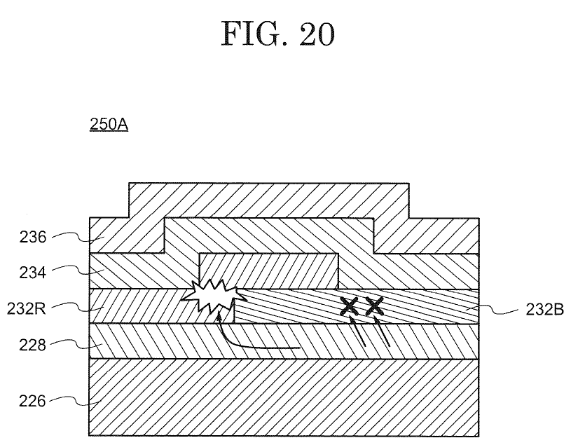

FIG. 18 is an enlarged view of a pixel layout when a conventional display device 200 is in a plan view, and FIG. 19 is a cross-sectional view when the display device 200 shown in FIG. 18 is cut along a line F1-F2. FIG. 20 is an enlarged view of part of the cross-sectional view shown in FIG. 19.

FIG. 18 shows a region where pixels 205R, 205G, and 205B are arranged. The pixel 205R and the pixel 205B are arranged side by side in the direction X. The pixel 205G and the pixel 205B are arranged side by side in the direction X. In FIG. 18, a region indicated by a solid line is a region where light-emitting layers 232R, 232G, and 232B are arranged. In addition, a region surrounded by a dotted line is a region where openings 220R, 220G, and 220B in the insulating layer are arranged. The openings 220R, 220G, and 220B arranged in the insulating layer correspond to the light-emitting region when light-emitting elements 230R, 230G, and 230B actually emit light. In addition, the light-emitting elements 230R, 230G, and 230B are referred to as the light-emitting element 230 when they are not distinguished from each other. The same applies to each component of the light-emitting elements 230R, 230G, and 230B.

As shown in FIG. 18, the light-emitting layer 232R and the light-emitting layer 232B partially overlap at a border area between the adjacent pixel 205R and the pixel 205B. In addition, the light-emitting layer 232B and the light-emitting layer 232G partially overlap at a border area between the adjacent pixel 205B and the pixel 205G.

FIG. 19 shows a cross-sectional view of the pixels 205R, 205G, and 205B. On the insulating film 222, the light-emitting element 230R is arranged in the pixel 205R, the light-emitting element 230G is arranged in the pixel 205G, and the light-emitting element 230B is arranged in the pixel 205B. The light-emitting element 230R has at least a pixel electrode 224R, the light-emitting layer 232R, and a counter electrode 236. The light-emitting element 230G has at least a pixel electrode 224G, the light-emitting layer 232G, and the counter electrode 236. The light-emitting element 230B has at least a pixel electrode 224B, the light-emitting layer 232B, and the counter electrode 236. A common layer 228 is arranged between the pixel electrodes 224R, 224G, and 224B and the light-emitting layers 232R, 232G, and 232B. A common layer 234 is arranged between the light-emitting layers 232R, 232G, and 232B and the counter electrode 136. The common layers 228 and 234 are arranged in common over the light-emitting elements 230R, 230G, and 230B (over the display region). In FIG. 18 to FIG. 20, the pixel electrodes 224R, 224G, and 224B are anodes and the counter electrode 236 is a cathode. Therefore, the common layer 228 includes at least one of the hole transport layer and the hole injection layer, and the common layer 234 includes at least one of the electron transport layer and the electron injection layer.

In order to suppress unintended light emission in adjacent pixels, it is preferable that the regions arranged with the light-emitting layer are separated from each other so as not to overlap each other. However, in order for the regions arranged with the light-emitting layer to be formed so as not to overlap each other, the openings 220R, 220G, and 220B need to be formed sufficiently separated, thereby deteriorating the definition.

Therefore, as the definition of the display region is increased, the regions arranged with the light-emitting layer may overlap each other. As shown in FIG. 18 to FIG. 20, in a region where the pixel 205B and the pixel 205R are adjacent to each other, part of the light-emitting layer 232B and part of the light-emitting layer 232R may overlap.

FIG. 20 shows an enlarged view of a region 250A where the pixel 205B and the pixel 205R are adjacent to each other. On an insulating layer 226, the light-emitting layer 232B and the light-emitting layer 232R are arranged on the common layer 228. Part of the light-emitting layer 232B overlaps part of the light-emitting layer 232R. Generally, an emission starting voltage of the light-emitting layer 232B is greater than emission starting voltages of a light-emitting layer 228R and the light-emitting layer 232G. Therefore, when the light-emitting element 230B is caused to emit light, a large voltage is applied to the light-emitting layer 232B, so that the hole in the common layer 228 moves in the transverse direction from the pixel 205B toward the pixel 205R and the pixel 205. In the case where the light-emitting layer 232B exhibits hole-transport properties, the hole passes through the light-emitting layer 232B in the thickness direction. Therefore, the light-emitting layer 232R emits light at an end portion of the light-emitting layer 232R. Alternatively, in the case where the light-emitting layer 232B exhibits electron-transport properties, the hole does not pass through the light-emitting layer 232B in the thickness direction but moves in the transverse direction. Therefore, the light-emitting layer 232R emits light in the vicinity of an end portion of the light-emitting layer 232B. In the present specification and the like, a portion where unintended light emission occurs in the light-emitting layer 232R or the light-emitting layer 232G adjacent to the light-emitting layer 232B is referred to as a starting point of light emission. In addition, the emission starting voltage of the light-emitting layer 232R and the emission starting voltage of the light-emitting layer 232G are approximately the same. As a result, even if the light-emitting element 230G is caused to emit light, the hole in the common layer 228 is suppressed from moving in the transverse direction from the pixel 205G toward the pixel 205R and the pixel 205B. Therefore, an end portion of the light-emitting layer 232G and the light-emitting layer 232R do not emit light in a region where the end portion of the light-emitting layer 232G overlaps the light-emitting layer 232R.

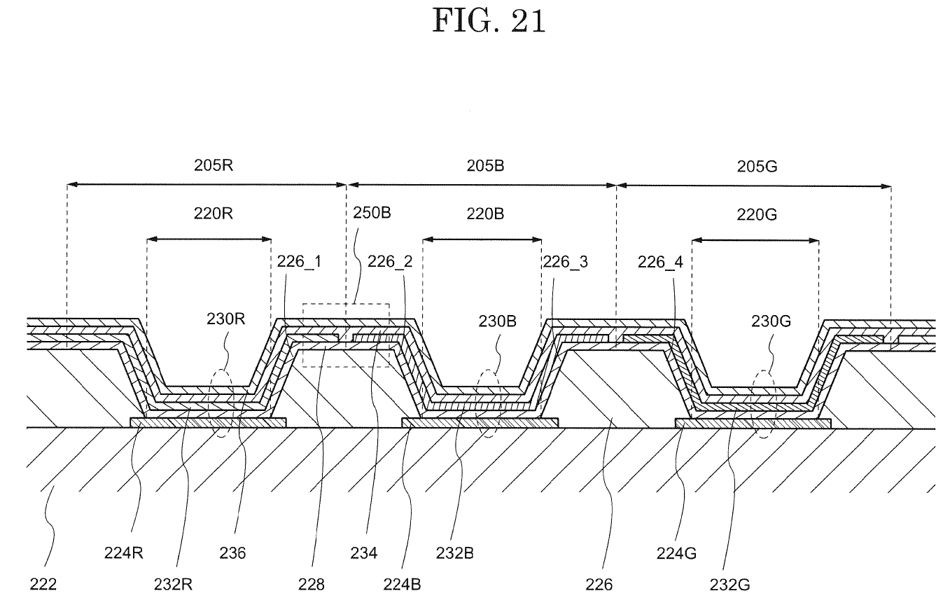

As shown in FIG. 21, in the region where the pixel 205B and the pixel 205R are adjacent to each other, part of the light-emitting layer 232B and part of the light-emitting layer 232R may be separated.

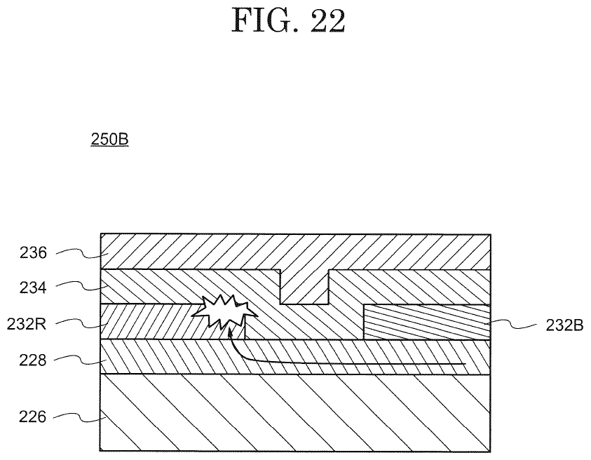

FIG. 22 shows an enlarged view of a region 250B where the pixel 205B and the pixel 205R are adjacent to each other. On the insulating layer 226, the light-emitting layer 232B and the light-emitting layer 232R are arranged on the common layer 228. The end portion of the light-emitting layer 232B is separated from the end portion of the light-emitting layer 232R. An emission starting voltage of the light-emitting layer 132B is greater than emission starting voltages of a light-emitting layer 228G and the light-emitting layer 132R. Therefore, when the light-emitting element 230B is caused to emit light, a large voltage is applied to the light-emitting layer 232B, so that the hole in the common layer 228 moves in the transverse direction from the pixel 205B toward the pixel 205G and the pixel 205R. In the case where the light-emitting layer 232B exhibits hole-transport properties, the hole passes through the light-emitting layer 232B in the thickness direction. Therefore, the light-emitting layer 232R emits light at the end portion of the light-emitting layer 232R. Alternatively, in the case where the light-emitting layer 232B exhibits electron-transport properties, the hole does not pass through the light-emitting layer 232B in the thickness direction but moves in the transverse direction. Therefore, the light-emitting layer 232R emits light even if the end portion of the light-emitting layer 232R is separated from the end portion of the light-emitting layer 232B.

As described above, since the emission starting voltages of the light-emitting layers 232R, 232G, and 232B are different from each other, even if the light-emitting layer 232B and the adjacent light-emitting layer 232R and the light-emitting layer 232G overlap or do not overlap, a leakage current in the transverse direction is generated, and the emitting layer emits light in an unintended region. In order to suppress unintended light emission in each light-emitting layer, it is conceivable to suppress the leakage current in the transverse direction by designing the emission starting voltages of the light-emitting layers 232R, 232G, and 232B to coincide with each other. However, the characteristics of the light-emitting element and the design for suppressing carrier injection into the light-emitting layer are required, resulting in a trade-off between the characteristics of the light-emitting element. As described above, conventionally, it has been difficult to prevent unintentional light emission caused by the leakage current in the transverse direction while improving the characteristics of the light-emitting element.

As described in FIG. 18 to FIG. 22, the starting point of the light emission differs depending on the order in which the common layer 228 and the light-emitting layers 232R, 232G, and 232B are stacked. In addition, the strength of the leakage current in the transverse direction depends on the distance of the light-emitting element 230B from the light-emitting region. Therefore, in the case where the distance between the light-emitting region of the light-emitting element 230B and the end portion of the light-emitting layer 232B is small, the strength of the leakage current increases. Therefore, the intensity of unintended light emission in the light-emitting layer 132R and the light-emitting layer 132G arranged overlapping with or separated from the end portion of the light-emitting layer 232B also increases.

Therefore, in the display device 100 according to an embodiment of the present invention, the light-emitting region of the light-emitting element 130B which has a larger emission starting voltage than the emission starting voltage of the light-emitting elements 130R and 130G is arranged separated from the end portion of the light-emitting layer 132B where unintended light emission is likely to occur. In other words, a region where the light-emitting layers 132R and 132G of the light-emitting elements 130R and 130G which have a lower emission starting voltages does not overlap the light-emitting layer 132B is located further separated from the light-emitting element 130B.

FIG. 4 is an enlarged view of part of the cross-sectional view shown in FIG. 3. FIG. 4 shows an enlarged area of a border between the light-emitting element 130B and the light-emitting element 130R. As shown in FIG. 4, an end portion 132B-1 of the light-emitting layer 132B is arranged so as to be close to the light-emitting region (the opening 120R) of the light-emitting element 130R. The end portion 132B-1 of the light-emitting layer 132B is arranged on the inclined surface 126-1 of the opening 120R arranged in the insulating layer 126. In addition, an end portion 132R-1 of the light-emitting layer 132R overlaps the light-emitting layer 132B. A distance from an end portion of the opening 120B to an end portion of the opening 120R is defined as d1. In this case, the end portion of the opening 120B refers to a portion in contact with the pixel electrode 124B. In addition, the end portion of the opening 120R refers to a portion in contact with the pixel electrode 124R. The end portion 132R-1 of the light-emitting layer 132R is arranged closer to the opening 120B than an intermediate portion d1/2 between the end portion of the opening 120R and the end portion of the opening 120B.

Although not shown in detail in FIG. 4, the end portion of the light-emitting layer 132B adjacent to the light-emitting layer 132G is similar to the end portion 132B-1 of the light-emitting layer 132B. That is, the end portion 132B-1 of the light-emitting layer 132B is arranged so as to be close to the light-emitting region (the opening 120G) of the light-emitting element 130G. The end portion 132B-1 of the light-emitting layer 132B is arranged on the inclined surface 126-3 of the opening 120G arranged in the insulating layer 126. In addition, an end portion of the light-emitting layer 132G overlaps the light-emitting layer 132B. A distance from the end portion of the opening 120B to an end portion of the opening 120G is defined as d2. In this case, the end portion of the opening 120G refers to a portion in contact with the pixel electrode 124G. The end portion of the light-emitting layer 132G is arranged closer to the opening 120B than an intermediate portion d2/2 between the end portion of the opening 120G and the end portion of the opening 120B.

In this way, arranging the light-emitting region of the light-emitting element 130B separated from the end portion of the light-emitting layer 132B where unintended light emission is likely to occur makes it possible to increase the distance between the light-emitting region of the light-emitting element 130B and the end portion of the light-emitting layer 132B. Therefore, the strength of the leakage current in the transverse direction from the light-emitting element 130B can be reduced at the end portion of the light-emitting layer 132B. As a result, it is possible to suppress the occurrence of unintended light emission in the light-emitting layer 132R or the light-emitting layer 132G.

The light-emitting layer 132B in contact with the common layer 128 including at least one of the hole transport layer and the hole injection layer preferably includes an electron-transporting light-emitting material. When the light-emitting element 130B emits light, it is possible to suppress the hole in the common layer 128 from passing through the light-emitting layer 132B in the thickness direction. Since the hole passes through the end portion of the light-emitting layer 132B in the transverse direction, the strength of the leakage current in the transverse direction can be further reduced. As a result, it is possible to suppress the occurrence of unintended light emission in the light-emitting layer 132R or the light-emitting layer 132G.

Although not shown in FIG. 3 and FIG. 4, a sealing film may be arranged on the light-emitting elements 130R, 130G, and 130B. The sealing film is configured by combining an inorganic insulating film and an organic insulating film. As a result, it is possible to suppress water from entering the organic layer including the light-emitting layer 132 and the common layers 128 and 134 into the light-emitting elements 130R, 130G, and 130B.

### [Manufacturing Method of Display Device]

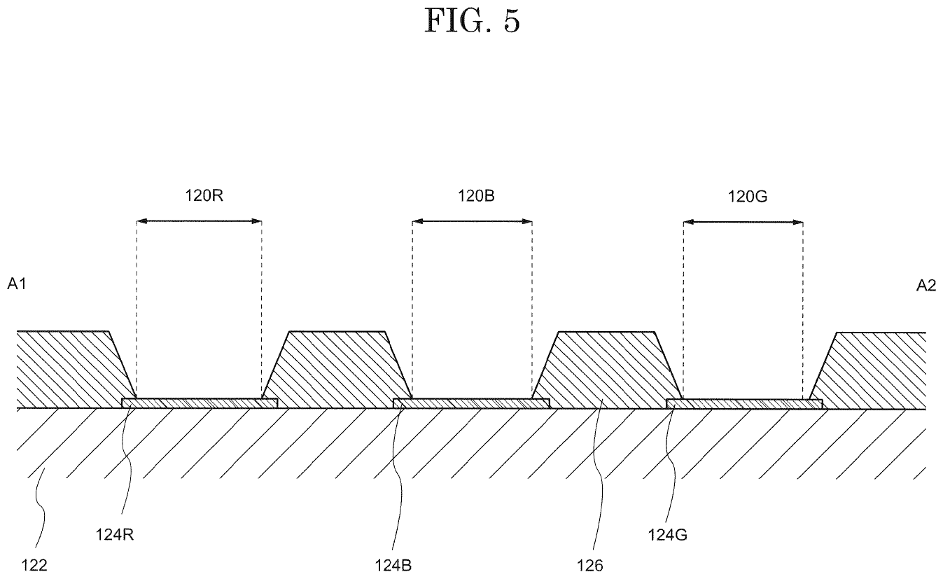

Next, a manufacturing method of the display device 100 will be described with reference to FIG. 5 to FIG. 7.

Although not shown in FIG. 5 to FIG. 7, a transistor constituting the pixel circuit is arranged on the substrate 101. In addition, as for the manufacturing method of the pixel circuit formed on the substrate 101, a known manufacturing method of the transistor may be applied, and thus a detailed explanation thereof is omitted. An interlayer insulating film containing at least one of silicon oxide and silicon nitride is formed on the transistor. A source electrode or drain electrode is formed on the interlayer insulating film.

FIG. 5 is a diagram illustrating a process of forming the insulating film 122, the pixel electrodes 124R, 124G, and 124B, and the insulating layer 126. The insulating film 122 functions as a planarization film. The insulating film 122 is composed of an organic resin material. A known organic resin material such as a polyimide-based resin, polyamide-based resin, acrylic-based resin, epoxy-based resin, or siloxane-based resin can be used as the organic resin material. Arranging the insulating film 122 on the transistor or the interlayer insulating film makes it possible to reduce the unevenness of the transistor. A contact hole is formed in the insulating film 122.

The pixel electrodes 124R, 124G, and 124B are formed on the insulating film 122. Each of the pixel electrodes 124R, 124G, and 124B is electrically connected to the source electrode or drain electrode connected to the transistor via the contact hole arranged in the insulating film 122. In the present embodiment, the pixel electrodes 124R, 124G, and 124B function as anodes. A highly reflective metal film is used as the pixel electrodes 124R, 124G, and 124B. Alternatively, a stacked structure of a transparent conductive layer with a high work function such as an indium-oxide-based transparent conductive layer (for example, ITO) or a zinc-oxide-based transparent conductive layer (for example, IZO, ZnO) and the metal film is used as the pixel electrodes 124R, 124G, and 124B.

The insulating layer 126 composed of an organic resin material is formed on the pixel electrodes 124R, 124G, and 124B. A known organic resin material such as a polyimide-based resin, polyamide-based resin, acrylic-based resin, epoxy-based resin, or siloxane-based resin can be used as the organic resin material. The insulating layer 126 has the openings 120R, 120G, and 120B in each of a portion on the pixel electrode 124R, a portion of the pixel electrode 124G, and a portion of the pixel electrode 124B. The insulating layer 126 is arranged between the adjacent pixel electrodes 124R, 124G, and 124B so as to cover end portions (edge portions) of the pixel electrodes 124R, 124G, and 124B. The insulating layer 126 functions as a member that separates the adjacent pixel electrodes 124R, 124G, and 124B. For this reason, the insulating layer 126 is also generally called a “barrier” or a “bank.” Part of the pixel electrodes 124R, 124G, and 124B exposed by the openings 120R, 120G, and 120B of the insulating layer 126 becomes the light-emitting region of the light-emitting elements 130R, 130G, and 130B. The openings 120R, 120G, and 120B of the insulating layer 126 is preferably such that the inner wall is tapered shape. As a result, when forming the common layer 128 and the light-emitting layers 132R, 132G, and 132B, which will be described later, it is possible to reduce a coverage defect at the end portions of the pixel electrodes 124R, 124G, and 124B.

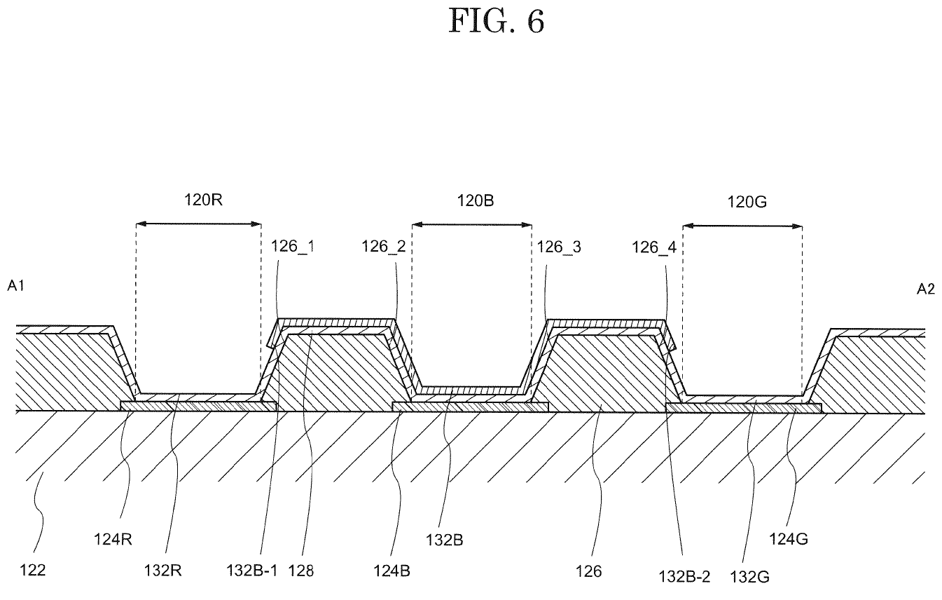

FIG. 6 is a diagram illustrating a process of forming the common layer 128 and the light-emitting layer 132B. The common layer 128 is formed on the pixel electrodes 124R, 124G, and 124B and the insulating layer 126. The common layer 128 includes at least one of the hole transport layer and the hole injection layer. Known materials may be used as the hole transport layer and the hole injection layer as appropriate.

The light-emitting layers 132R, 132G, and 132B are preferably formed in the order from the light-emitting layer having the highest emission starting voltage. In the present embodiment, the emission starting voltage of the light-emitting layer 132B is higher than the emission starting voltages of the light-emitting layer 132R and the light-emitting layer 132G. Therefore, the light-emitting layer 132B is first formed on the common layer 128. The end portion 132B-1 of the light-emitting layer 132B is formed so as to be arranged on the inclined surface 126-1 of the opening 120R arranged in the insulating layer 126. In addition, the end portion 132B-1 of the light-emitting layer 132B is formed so as to be arranged on the inclined surface 126-3 of the opening 120G arranged in the insulating layer 126. Further, the light-emitting layer 132B is preferably a light-emitting material having electron-transport properties, and a known material may be appropriately used.

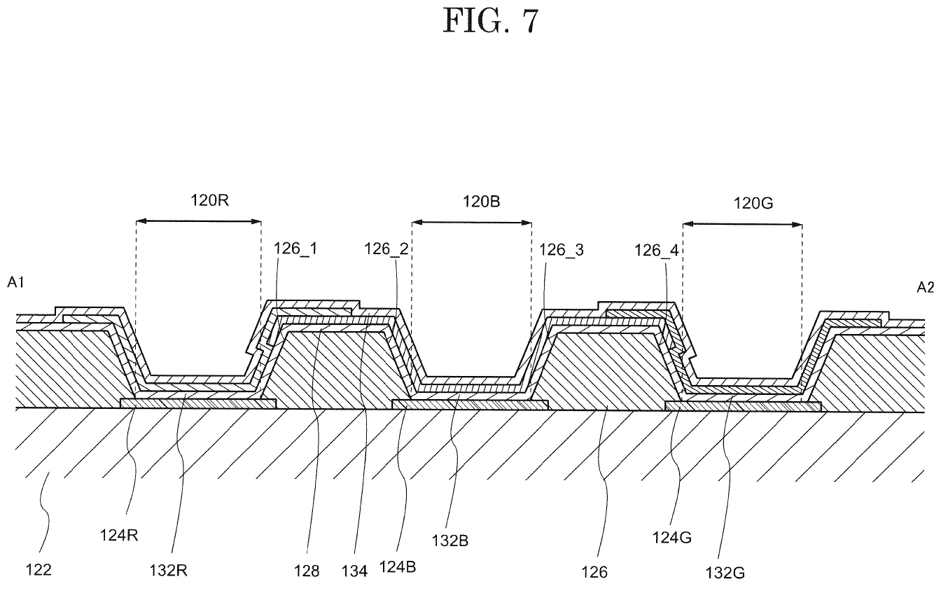

FIG. 7 is a diagram illustrating a process of forming the light-emitting layer 132R, the light-emitting layer 132G, and the common layer 134. The light-emitting layer 132R is formed in the opening 120R. A first end portion of the light-emitting layer 132R is formed to overlap the light-emitting layer 132B. Specifically, the first end portion of the light-emitting layer 132R is arranged closer to the opening 120B than the intermediate portion d1/2 between the end portion on an inclined surface 126-2 side in the opening 120B and the end portion on the inclined surface 126-1 side in the opening 120R. Next, the light-emitting layer 132G is formed in the opening 120G. A first end portion of the light-emitting layer 132G is formed to overlap the light-emitting layer 132B. Specifically, the first end portion of the light-emitting layer 132G is arranged closer to the opening 120B than the intermediate portion d2/2 between the end portion on the inclined surface 126-2 side in the opening 120B and the end portion on the inclined surface 126-3 side in the opening 120G.

Next, the common layer 134 is formed on the light-emitting layers 132R, 132G, and 132B. The common layer 134 includes at least one of the electron transport layer and the electron injection layer. Known materials may be used as the electron transport layer and the electron injection layer as appropriate.

Finally, the display device 100 shown in FIG. 3 can be formed by forming the counter electrode 136 on the common layer 134.

In the present embodiment, although the case where the light-emitting layer 132G is formed after the light-emitting layer 132R is formed has been described, the present invention is not limited to this. As long as the emission starting voltage of the light-emitting layer 132R and the emission starting voltage of the light-emitting layer 132G are approximately the same, either layer may be formed first. Alternatively, if there is a difference between the emission starting voltage of the light-emitting layer 132R and the emission starting voltage of the light-emitting layer 132G, the light-emitting layer having a higher emission starting voltage may be formed first.

In the present embodiment, although the overlap between the end portion of the light-emitting layer 132R and the end portion of the light-emitting layer 132G adjacent to each other is not shown, the end portion of the light-emitting layer 132R and the end portion of the light-emitting layer 132G adjacent to each other may or may not overlap. This is because, if the emission starting voltage of the light-emitting layer 132R and the emission starting voltage of the light-emitting layer 132G are approximately the same, even if the light-emitting element 130R or the light-emitting element 130G emits light, the effect of the leakage current in the transverse direction from the light-emitting layer 132R and the light-emitting layer 132G is small.

The display device 100 according to an embodiment of the present invention is not limited to the configuration shown in FIG. 2 to FIG. 4. For example, the arrangement of the pixels 105R, 105G, and 105B is not limited to the arrangement of the pixels 105R, 105G, and 105B shown in FIG. 2.

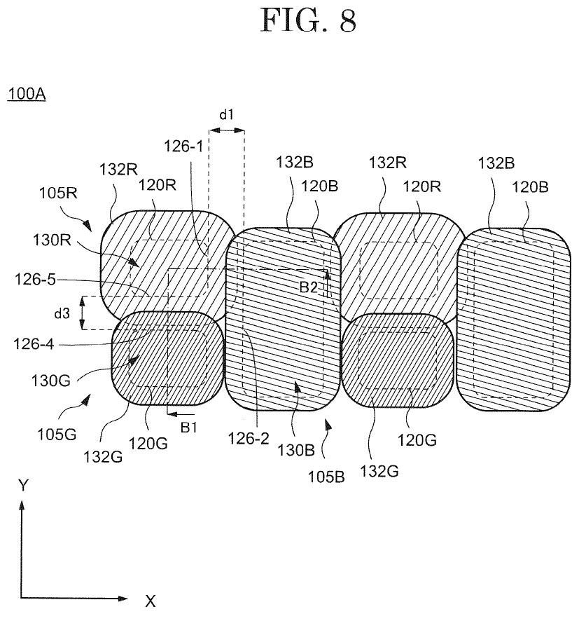

Next, display devices 100A to 100F according to Modifications 1 to 6 in which part of the constituent elements of the display device 100 is modified will be described with reference to FIG. 8 to FIG. 17. In the display devices 100A to 100E according to Modifications 1 to 5, the arrangement of the light-emitting layers 132R, 132G, and 132B is different from the arrangement in the display device 100. In addition, in the display device 100F according to Modification 6, the arrangement of the anode and the cathode is different from the arrangement of the anode and the cathode in the display device 100. In the following description, the same components as those of the display device 100 may be referred to in the description of FIG. 2 to FIG. 4.

### [Modification 1]

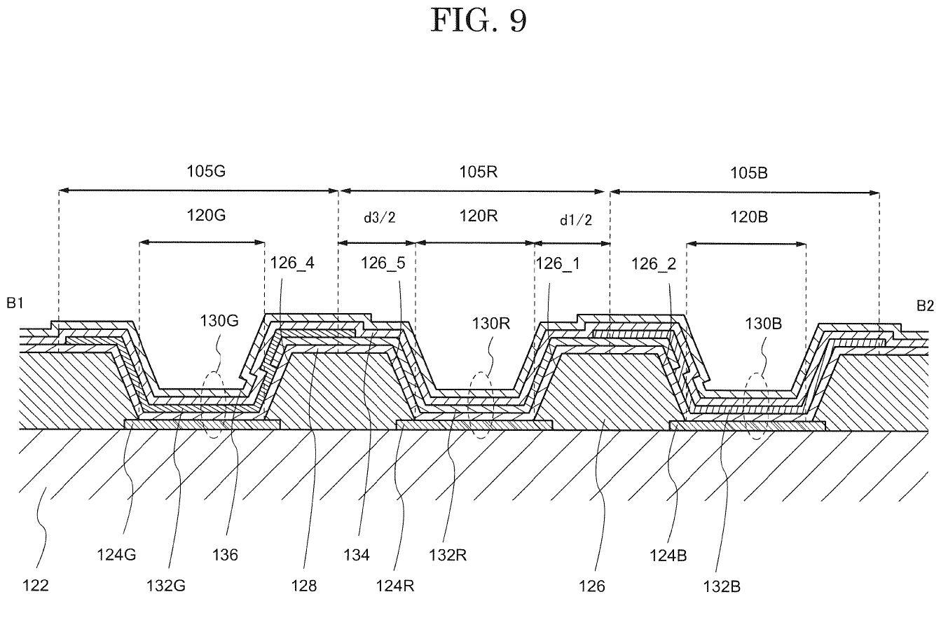

FIG. 8 is a pixel layout diagram when the display device 100A according to an embodiment of the present invention is in a plan view. In addition, FIG. 9 is a cross-sectional view when the display device 100A shown in FIG. 8 is cut along a line B1-B2. In Modification 1, the case where the emission starting voltage of the light-emitting layer 132R is higher than the emission starting voltages of the light-emitting layer 132G and the light-emitting layer 132B will be described.

FIG. 8 shows a region where the pixels 105R, 105G, and 105B in the display device 100A are arranged. In the display device 100A, the stacking order of the light-emitting layers 132R, 132G, and 132B is different from that in the display device 100. In the display device 100A, an overlapping region of the light-emitting layer 132R and the light-emitting layer 132G and an overlapping region of the light-emitting layer 132R and the light-emitting layer 132B are different from that in the display device 100.

As described with reference to FIG. 6, the light-emitting layer having the highest emission starting voltage among the light-emitting layers 132R, 132G, and 132B is preferably arranged on the common layer 128. Therefore, the light-emitting layer 132R is first arranged on the common layer 128. The first end portion of the light-emitting layer 132R is arranged so as to be close to the light-emitting region (the opening 120G) of the light-emitting element 130G. The first end portion of the light-emitting layer 132R is arranged on an inclined surface 126-4 of the opening 120G arranged in the insulating layer 126. The second end portion of the light-emitting layer 132R is arranged so as to be close to the light-emitting region (the opening 120B) of the light-emitting element 130B. The first end portion of the light-emitting layer 132R is arranged on the inclined surface 126-2 of the opening 120B arranged in the insulating layer 126. In addition, the light-emitting layer 132R is preferably a light-emitting material having electron-transport properties, and a known material can be appropriately used.

The light-emitting layer 132G is arranged in the opening 120G. The first end portion of the light-emitting layer 132G is arranged so as to be close to the light-emitting region (the opening 120R) of the light-emitting element 130R. The first end portion of the light-emitting layer 132G is formed to overlap the light-emitting layer 132R. A distance from the end portion of the opening 120R to the end portion of the opening 120G is defined as d3. The first end portion of the light-emitting layer 132G is arranged closer to the opening 120R than an intermediate portion d3/2 between the end portion of the opening 120R and the end portion of the opening 120G. Next, the light-emitting layer 132B is formed in the opening 120B. The first end portion of the light-emitting layer 132B is formed to overlap the light-emitting layer 132R. The first end portion of the light-emitting layer 132B is arranged closer to the opening 120R than the intermediate portion d1/2 between the end portion of the opening 120B and the end portion of the opening 120R.

As described above, arranging the light-emitting region of the light-emitting element 130R separated from the end portion of the light-emitting layer 132R where unintended light emission is likely to occur makes it possible to increase the distance between the light-emitting region of the light-emitting element 130R and the end portion of the light-emitting layer 132R. Therefore, the strength of the leakage current in the transverse direction from the light-emitting element 130R can be reduced at the end portion of the light-emitting layer 132R. As a result, it is possible to suppress the occurrence of unintended light emission in the light-emitting layer 132G or the light-emitting layer 132B.

The light-emitting layer 132R in contact with the common layer 128 including at least one of the hole transport layer and the hole injection layer preferably includes an electron-transporting light-emitting material. When the light-emitting element 130R emits light, it is possible to suppress the hole in the common layer 128 from passing through the light-emitting layer 132R in the thickness direction. Since the hole passes through the end portion of the light-emitting layer 132R in the transverse direction, the strength of the leakage current in the transverse direction can be further reduced. As a result, it is possible to suppress the occurrence of unintended light emission in the light-emitting layer 132G or the light-emitting layer 132B.

### [Modification 2]

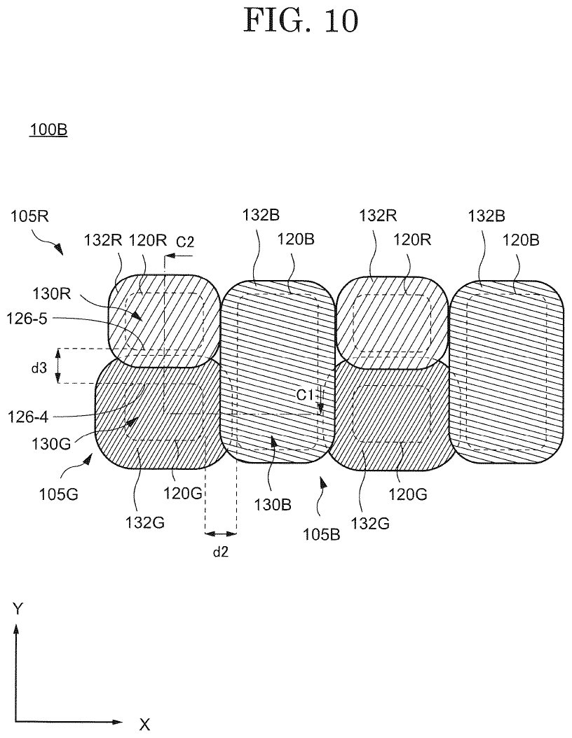

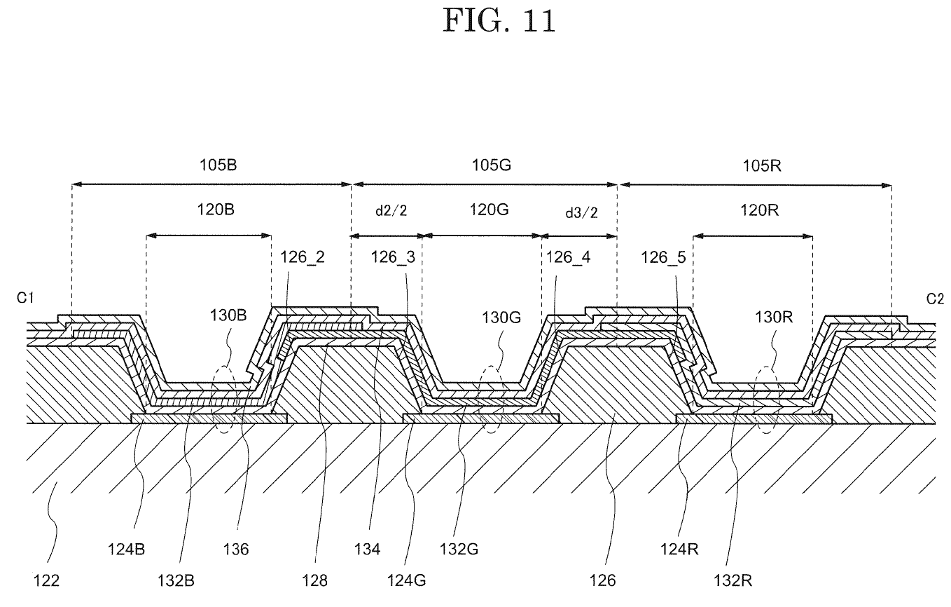

FIG. 10 is a pixel layout diagram when the display device 100B according to an embodiment of the present invention is in a plan view. In addition, FIG. 11 is a cross-sectional view when the display device 100A shown in FIG. 10 is cut along a line C1-C2. In Modification 2, the case where the emission starting voltage of the light-emitting layer 132G is higher than the emission starting voltages of the light-emitting layer 132R and the light-emitting layer 132B will be described.

FIG. 10 shows a region where the pixels 105R, 105G, and 105B in the display device 100B are arranged. In the display device 1006, the stacking order of the light-emitting layers 132R, 132G, and 132B is different from that in the display device 100. In addition, in the display device 1006, an overlapping region of the light-emitting layer 132G and the light-emitting layer 132B and an overlapping region of the light-emitting layer 132G and the light-emitting layer 132R are different from that in the display device 100.

As described with reference to FIG. 6, the light-emitting layer having the highest emission starting voltage among the light-emitting layers 132R, 132G, and 132B is preferably arranged on the common layer 128. Therefore, the light-emitting layer 132G is first arranged on the common layer 128. The first end portion of the light-emitting layer 132G is arranged so as to be close to the light-emitting region (the opening 120B) of the light-emitting element 130B. The first end portion of the light-emitting layer 132G is formed to be arranged on the inclined surface 126-2 of the opening 120B arranged in the insulating layer 126. In addition, a second end portion of the light-emitting layer 132G is arranged on an inclined surface 126-5 of the opening 120R arranged in the insulating layer 126. Further, the light-emitting layer 132G is preferably a light-emitting material having electron-transport properties, and a known material can be appropriately used.

The light-emitting layer 132B is arranged in the opening 120B. The first end portion of the light-emitting layer 132B is arranged so as to be close to the light-emitting region (the opening 120G) of the light-emitting element 130G. The first end portion of the light-emitting layer 132B is formed to overlap the light-emitting layer 132G. The first end portion of the light-emitting layer 132B is arranged closer to the opening 120G than the intermediate portion d2/2 between the end portion of the opening 120B and the end portion of the opening 120G. Next, the light-emitting layer 132R is formed in the opening 120R. The first end portion of the light-emitting layer 132R is formed to overlap the light-emitting layer 132G. The first end portion of the light-emitting layer 132R is arranged closer to the opening 120R than the intermediate portion d3/2 between the end portion of the opening 120G and the end portion of the opening 120R.

As described above, arranging the light-emitting region of the light-emitting element 130G separated from the end portion of the light-emitting layer 132G where unintended light emission is likely to occur makes it possible to increase the distance between the light-emitting region of the light-emitting element 130G and the end portion of the light-emitting layer 132G. Therefore, the strength of the leakage current in the transverse direction from the light-emitting element 130G can be reduced at the end portion of the light-emitting layer 132G. As a result, it is possible to suppress the occurrence of unintended light emission in the light-emitting layer 132R or the light-emitting layer 132B.

The light-emitting layer 132G in contact with the common layer 128 including at least one of the hole transport layer and the hole injection layer preferably includes an electron-transporting light-emitting material. When the light-emitting element 130G emits light, it is possible to suppress the hole in the common layer 128 from passing through the light-emitting layer 132G in the thickness direction. Since the hole passes through the end portion of the light-emitting layer 132G in the transverse direction, the strength of the leakage current in the transverse direction can be further reduced. As a result, it is possible to suppress the occurrence of unintended light emission in the light-emitting layer 132R or the light-emitting layer 132B.

### [Modification 3]

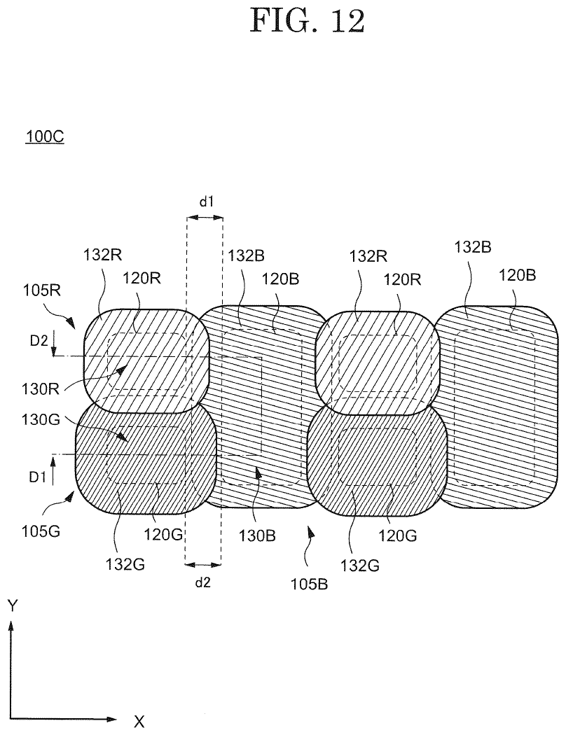

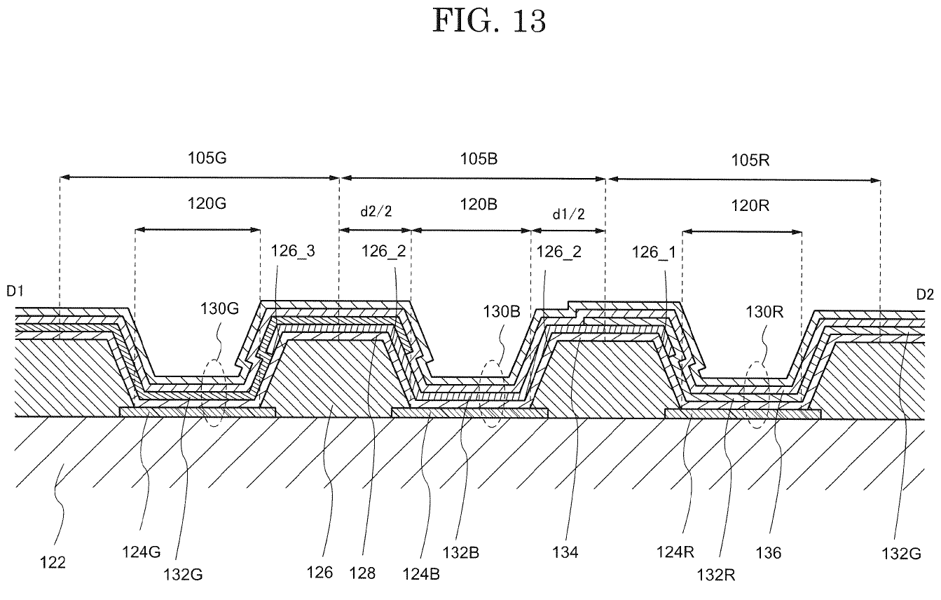

FIG. 12 is a pixel layout diagram when the display device 100C according to an embodiment of the present invention is in a plan view. In addition, FIG. 13 is a cross-sectional view when the display device 100A shown in FIG. 12 is cut along a line D1-D2. In Modification 3, the emission starting voltage of the light-emitting layer 132B is higher than the emission starting voltages of the light-emitting layer 132R and the light-emitting layer 132G, and the emission starting voltage of the light-emitting layer 132G is higher than the emission starting voltage of the light-emitting layer 132R.

FIG. 12 shows a region where the pixels 105R, 105G, and 105B in the display device 100C are arranged. In the display device 100C, the stacking order of the light-emitting layers 132R, 132G, and 132B is different from that in the display device 100. In addition, in the display device 100C, the overlapping region of the light-emitting layer 132B and the light-emitting layer 132G and the overlapping region of the light-emitting layer 132G and the light-emitting layer 132R are different from that in the display device 100.

As described with reference to FIG. 6, the light-emitting layer having the highest emission starting voltage among the light-emitting layers 132R, 132G, and 132B is preferably arranged on the common layer 128. Therefore, the light-emitting layer 132B is first arranged on the common layer 128. In FIG. 11, a region where the light-emitting layer 132B is arranged is the same as the region where the light-emitting layer 132B shown in FIG. 3 is arranged. In addition, the light-emitting layer 132B is preferably a light-emitting material having electron-transport properties, and a known material can be appropriately used.

Next, the light-emitting layer 132G having the second highest emission starting voltage after the light-emitting layer 132B is arranged in the opening 120G. In a region where the light-emitting layer 132G is arranged, the first end portion of the first light-emitting layer 132G is arranged so as to be close to the light-emitting region (the opening 120B) of the light-emitting element 130B. The first end portion of the light-emitting layer 132G is formed to be arranged on the inclined surface 126-2 of the opening 120B arranged in the insulating layer 126. In addition, the light-emitting layer 132G is preferably a light-emitting material having electron-transport properties, and a known material can be appropriately used. Finally, the light-emitting layer 132R is arranged in the opening 120R. The first end portion of the light-emitting layer 132R is arranged closer to the opening 120B than the intermediate portion d1/2 between the end portion of the opening 120R and the end portion of the opening 120B. Although not shown in FIG. 13, at the border between the light-emitting layer 132G and the light-emitting layer 132R, the second end portion of the light-emitting layer 132G is formed to be arranged on the inclined surface 126-5 of the opening 120R arranged in the insulating layer 126.

As described above, arranging the light-emitting region of the light-emitting element 130B separate from the end portion of the light-emitting layer 132B where unintended light emission is likely to occur makes it possible to increase the distance between the light-emitting region of the light-emitting element 130B and the end portion of the light-emitting layer 132B. Therefore, the strength of the leakage current in the transverse direction from the light-emitting element 130B can be reduced at the end portion of the light-emitting layer 132B. Furthermore, arranging the light-emitting region of the light-emitting element 130G separate from the end portion of the light-emitting layer 132G where unintended light emission is likely to occur makes it possible to increase the distance between the light-emitting region of the light-emitting element 130G and the end portion of the light-emitting layer 132G. Therefore, the strength of the leakage current in the transverse direction from the light-emitting element 130G can be reduced at the end portion of the light-emitting layer 132G. As a result, it is possible to further suppress the occurrence of unintended light emission in the light-emitting layer 132G or the light-emitting layer 132R.

In the display device 100C according to Modification 3, although the case where the light-emitting layers 132B, 132G, and 132R are formed in the order of higher emission starting voltage has been described, an embodiment of the present invention is not limited to this. In the case where the emission starting voltages are higher in the order of the light-emitting layers 132B, 132R, and 132G, they may be formed in the order of the light-emitting layers 132B, 132R, and 132G.

### [Modification 4]

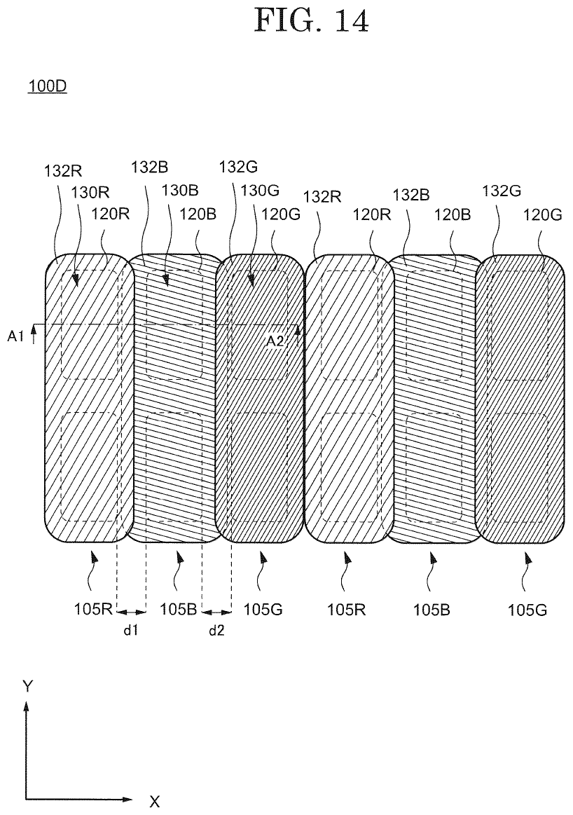

FIG. 14 is a pixel layout diagram when the display device 100D according to an embodiment of the present invention is in a plan view. In Modification 4, the case where the light-emitting layers 132R, 132G, and 132B are arranged in a stripe-like manner will be described. In Modification 4, the case where the emission starting voltage of the light-emitting layer 132B is higher than the emission starting voltages of the light-emitting layer 132R and the light-emitting layer 132G will be described.

FIG. 14 shows a region where the pixels 105R, 105G, and 105B are arranged. The pixels 105R, 105G, and 105B are arranged side by side in the direction X. Each of the plurality of pixels 105R, the plurality of pixels 105G, and the plurality of pixels 105B is arranged side by side in the direction Y. In the display device 100D, the stacking order of the light-emitting layers 132R, 132G, and 132B is the same as that in the display device 100.

In a region where the light-emitting layer 132B and the light-emitting layer 132R are adjacent to each other, the end portion of the light-emitting layer 132B is arranged so as to be close to the opening 120G of the light-emitting layer 132G. Since the end portion of the light-emitting layer 132B is separated from the light-emitting region of the light-emitting layer 132B, unintended light emission can be suppressed in the light-emitting layer 132R. In addition, in the region where the light-emitting layer 132B and the light-emitting layer 132G are adjacent to each other, the end portion of the light-emitting layer 132G is arranged so as to be close to the opening 120G. Since the end portion of the light-emitting layer 132B is separated from the light-emitting region of the light-emitting layer 132B, unintended light emission can be suppressed in the light-emitting layer 132G.

As described above, arranging the light-emitting region of the light-emitting element 130B separate from the end portion of the light-emitting layer 132B where unintended light emission is likely to occur makes it possible to increase the distance between the light-emitting region of the light-emitting element 130B and the end portion of the light-emitting layer 132B. Therefore, the strength of the leakage current in the transverse direction from the light-emitting element 130B can be reduced at the end portion of the light-emitting layer 132B. As a result, it is possible to further suppress the occurrence of unintended light emission in the light-emitting layer 132G or the light-emitting layer 132R.

### [Modification 5]

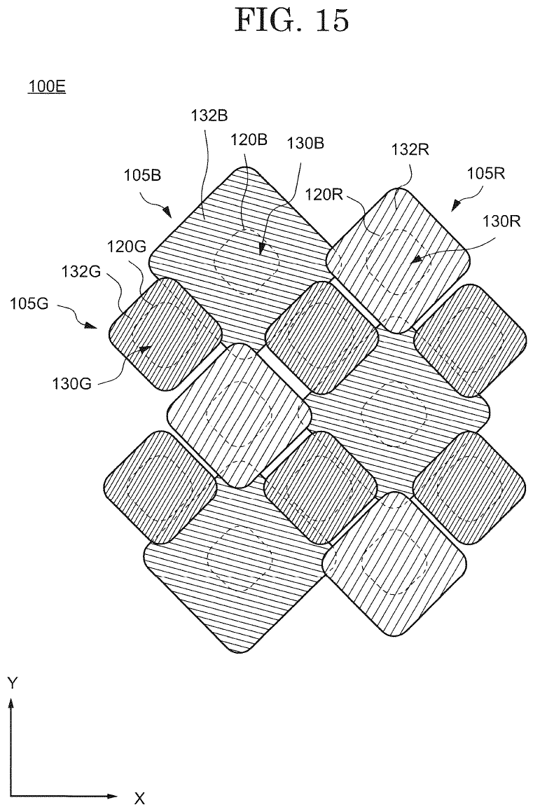

FIG. 15 is a pixel layout diagram when the display device 100E according to an embodiment of the present invention is in a plan view. In Modification 5, the case where the light-emitting elements 130R, 130G, and 130B are arranged in a pentile pattern.

FIG. 15 shows a region where the pixels 105R, 105G, and 105B are arranged. The plurality of pixels 105G is arranged side by side in the direction X. The pixel 105G and the pixel 105B are arranged side by side in the direction X. The pixel 105G and the pixel 105B are arranged side by side in a direction 8 with respect to the direction X. In addition, the pixel 105G and the pixel 105R are arranged side by side in the direction 8 with respect to the direction X. In the display device 100D, the stacking order of the light-emitting layers 132R, 132G, and 132B is the same as that in the display device 100.

In the region where the light-emitting layer 132B and the light-emitting layer 132G are adjacent to each other, the end portion of the light-emitting layer 132G is arranged so as to be close to the opening 120G of the light-emitting layer 132G. Therefore, since the end portion of the light-emitting layer 132B is separated from the light-emitting region of the light-emitting layer 132B, unintended light emission can be suppressed in the light-emitting layer 132G. On the other hand, at the region where the light-emitting layer 132B and the light-emitting layer 132R are adjacent to each other, the end portion of the light-emitting layer 132B is not arranged so as to be close to the opening 120R of the light-emitting layer 132R. However, since the end portion of the light-emitting layer 132B is sufficiently separated from the light-emitting region of the light-emitting element 130B, unintended light emission can be suppressed in the light-emitting layer 132R. In addition, the end portion of the light-emitting layer 132B may be arranged so as to be close to the opening 120R of the light-emitting layer 132R.

As described above, arranging the light-emitting region of the light-emitting element 130B separate from the end portion of the light-emitting layer 132B where unintended light emission is likely to occur makes it possible to increase the distance between the light-emitting region of the light-emitting element 130B and the end portion of the light-emitting layer 132B. Therefore, the strength of the leakage current in the transverse direction from the light-emitting element 130B can be reduced at the end portion of the light-emitting layer 132B. As a result, it is possible to further suppress the occurrence of unintended light emission in the light-emitting layer 132G or the light-emitting layer 132R.

In addition, in FIG. 15, the light-emitting element 130R and the light-emitting element 130B are positioned so that the corners of the light-emitting layers overlap. In such a positional relationship, the influence of the occurrence of the leakage current in the transverse direction is small compared with the light-emitting element 130G and the light-emitting element 130B in which the sides of the light-emitting regions are positioned so as to be parallel-adjacent to each other.

In the display device 100D and 100E shown in Modifications 3 and 4, the stacking order of the light-emitting layers 132R, 132G, and 132B is not limited. The light-emitting layer having the highest emission starting voltage among the light-emitting layers 132R, 132G, and 132B may be arranged at the bottom. In this case, the light-emitting layer having the highest emission starting voltage is preferably an electron-transporting light-emitting material.

### [Modification 6]

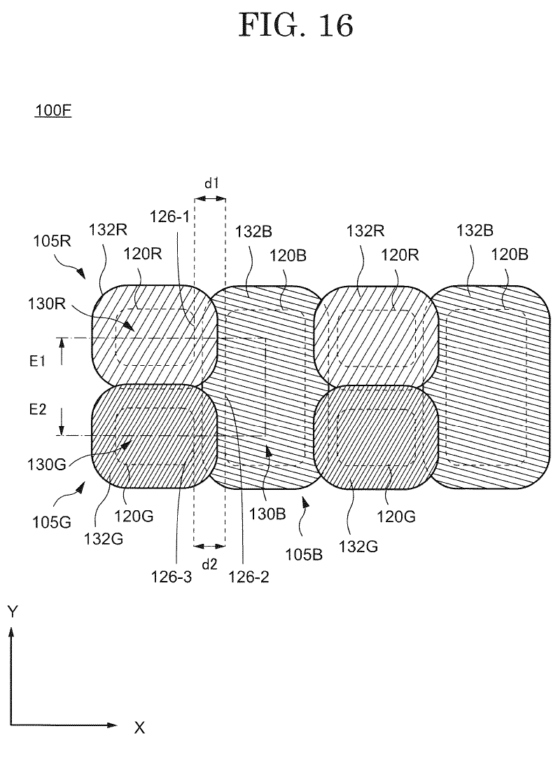

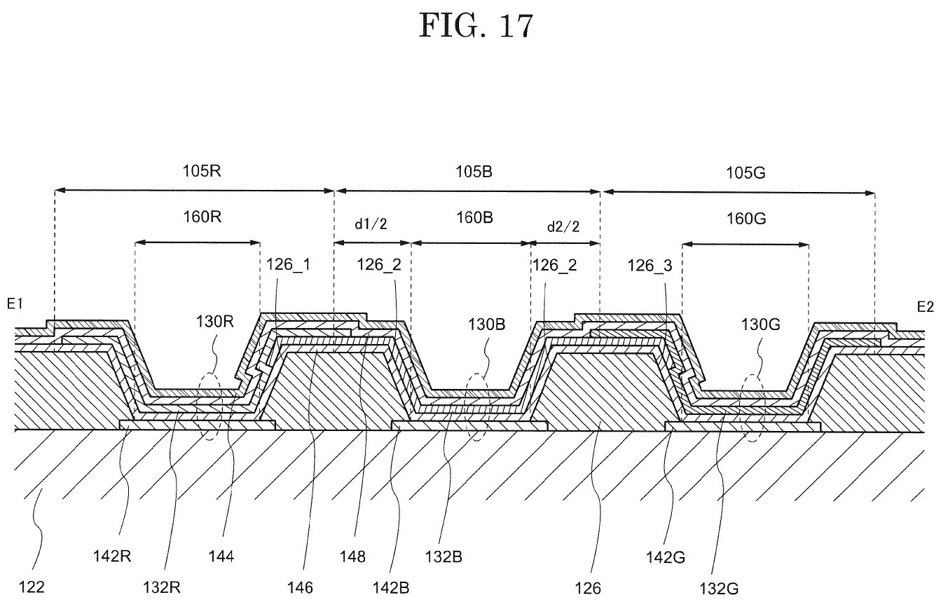

FIG. 16 is a pixel layout diagram when the display device 100F according to an embodiment of the present invention is in a plan view. In addition, FIG. 17 is a cross-sectional view when the display device 100A shown in FIG. 16 is cut along a line E1-E2. In Modification 6, the case where the emission starting voltage of the light-emitting layer 132B is higher than the emission starting voltages of the light-emitting layer 132R and the light-emitting layer 132G will be described.

FIG. 16 shows a region where the pixels 105R, 105G, and 105B are arranged. The arrangement of the pixels 105R, 105G, and 105B is the same as the arrangement of the pixels shown in FIG. 3.

FIG. 17 shows a cross-sectional view of the pixels 105R, 105G, and 105B. On the insulating film 122, a light-emitting element 160R is arranged in the pixel 105R, a light-emitting element 160G is arranged in the pixel 105G, and a light-emitting element 160B is arranged in the pixel 105B. The light-emitting element 160R has at least a pixel electrode 142R, the light-emitting layer 132R, and a counter electrode 144. The light-emitting element 160G has at least a pixel electrode 142G, the light-emitting layer 132G, and the counter electrode 144. The light-emitting element 160B has at least a pixel electrode 142B, the light-emitting layer 132B, and the counter electrode 144.

The display device 100F is different from the display device 100 in that the pixel electrodes 142R, 142G, and 142B function as the cathodes and the counter electrode 144 functions as the anode. Therefore, a common layer 146 arranged between the pixel electrodes 142R, 142G, and 142B and the light-emitting layers 132R, 132G, and 132B includes at least one of the electron transport layer and an electron injection layer. In addition, the common layer 148 arranged between the counter electrode 144 and the light-emitting layers 132R, 132G, and 132B includes at least one of the hole transport layer and the hole injection layer. Although not shown in FIG. 17, the pixel electrodes 124R, 124G, and 124B are electrically connected to the transistor 110 included in the pixel circuit.

The end portion of the light-emitting layer 132B adjacent to the light-emitting layer 132R is arranged so as to be close to the opening 120R of the light-emitting element 130R. The end portion of the light-emitting layer 132B is arranged on the inclined surface 126-1 of the opening 120R arranged in the insulating layer 126. In addition, the end portion of the light-emitting layer 132R overlaps the light-emitting layer 132B. The end portion of the light-emitting layer 132R is arranged closer to the opening 120B than the intermediate portion d1/2 between the end portion of the opening 120R and the opening 120B. The end portion of the light-emitting layer 132B adjacent to the light-emitting layer 132G is arranged so as to be close to the opening 120G of the light-emitting element 130G. The end portion of the light-emitting layer 132B is arranged on the inclined surface 126-3 of the opening 120G arranged in the insulating layer 126. In addition, the end portion of the light-emitting layer 132G overlaps the light-emitting layer 132B. The end portion of the light-emitting layer 132G is arranged closer to the opening 120B than the intermediate portion d2/2 between the end portion of the opening 120G and the end portion of the opening 120B.

In the display device 100F, in the light-emitting element 130, the pixel electrode 124 is used as a cathode and the counter electrode 136 is used as an anode. Even in this case, as in the case of the display device 100, arranging the light-emitting region of the light-emitting element 130B separate from the end portion of the light-emitting layer 132B where unintended light emission is likely to occur makes it possible to increase the distance between the light-emitting region of the light-emitting element 130B and the end portion of the light-emitting layer 132B. Therefore, the strength of the leakage current in the transverse direction from the light-emitting element 130B can be reduced at the end portion of the light-emitting layer 132B. As a result, it is possible to suppress the occurrence of unintended light emission in the light-emitting layer 132R or the light-emitting layer 132G.

The light-emitting layer 132B in contact with the common layer 146 including at least one of the electron transport layer and the electron injection layer preferably includes a hole transporting light-emitting material. When the light-emitting element 130B emits light, it is possible to suppress the electron in the common layer 128 from passing through the light-emitting layer 132B in the thickness direction. Since the electron passes through the end portion of the light-emitting layer 132B in the transverse direction, the strength of the leakage current in the transverse direction can be further reduced. As a result, it is possible to suppress the occurrence of unintended light emission in the light-emitting layer 132R or the light-emitting layer 132G.

In addition, a configuration of the display device 100F according to Modification 6 can be applied to the configurations according to the display devices 100A to 100E according to Modifications 1 to 5. In other words, in the display devices 100A to 100E according to Modifications 1 to 5, the pixel electrode 124 may be used as a cathode, and the counter electrode 136 may be used as an anode. In this case, the common layer arranged between the pixel electrode 124 and the light-emitting layer 132 includes at least one of the electron transport layer and the electron injection layer. In addition, the common layer arranged between the counter electrode 136 and light-emitting layer includes at least one of the hole transport layer and the hole injection layer. The light-emitting layer having the highest emission starting voltage among the light-emitting layers 132R, 132G, and 132B is preferably arranged on the common layer 128 including the electron transport layer and the electron injection layer. The light-emitting layer is preferably a light-emitting material having hole-transport properties.

As described above, the display device according to an embodiment of the present invention can be applied to various forms. Therefore, the addition, deletion, or design change of components, or the addition, deletion, or condition change of processes as appropriate by those skilled in the art based on the display devices 100, 100A to 100F of the present embodiment and modifications are also included in the scope of the present invention as long as they are provided with the gist of the present invention. In addition, each of the embodiments described above as an embodiment of the present invention can be appropriately combined as long as no contradiction is caused.

In addition, although the above-described embodiment mainly describes a display device having an organic EL element as a display element that suppresses a leakage current in an organic layer, the present invention is applicable not only to a display device but also to an optical sensor device or the like configured by arranging an organic photodiode in which an organic layer is sandwiched between electrodes in a matrix. Specifically, the present invention can be applied to the overlapping relationship of the end portions of the organic layers that are formed separately for coating among the organic layers that constitute the organic photodiode.

Further, it is understood that, even if the effect is different from those provided by each of the above-described embodiments, the effect obvious from the description in the specification or easily predicted by persons ordinarily skilled in the art is apparently derived from the present invention.

Within the spirit of the present invention, it is understood that various modifications and changes can be made by those skilled in the art and that these modifications and changes also fall within the scope of the present invention. For example, the addition, deletion, or design change of components, or the addition, deletion, or condition change of process as appropriate by those skilled in the art based on each embodiment are also included in the scope of the present invention as long as they are provided with the gist of the present invention.

What is claimed is:

1. A display device comprising:
a first pixel electrode;
a second pixel electrode arranged in a first direction and spaced apart from the first pixel electrode;
an insulating layer having a first opening exposing at least a portion of a top surface of the first pixel electrode and a second opening exposing at least a portion of a top surface of the second pixel electrode;
a first common layer arranged on the first pixel electrode, the second pixel electrode, and the insulating layer;
a first light-emitting layer arranged on the first common layer, and overlapping the first pixel electrode;
a second light-emitting layer arranged on the first common layer, overlapping the second pixel electrode, and having a lower emission starting voltage than that of the first light-emitting layer; and
a counter electrode arranged on the first light-emitting layer and the second light-emitting layer,
wherein
the first light-emitting layer is spread over the insulating layer and an edge the first light-emitting layer is arranged on an inclined surface of the second opening in the insulating layer, and the second light-emitting layer includes a region overlapping the first light-emitting layer.

2. The display device according to claim 1, wherein
the first light-emitting layer is arranged on the first common layer side, in a region where the first light-emitting layer and the second light-emitting layer are overlapped each other.

3. The display device according to claim 1, wherein
the first and second pixel electrodes are anodes, the first light-emitting layer has electron transport properties, and the first common layer has hole transport properties.

4. The display device according to claim 1, wherein
the first and second pixel electrodes are cathodes, the first light-emitting layer has hole transport properties, and the first common layer has electron transport properties.

5. The display device according to claim 1, wherein
an edge of the second light-emitting layer overlaps the first light-emitting layer and is arranged closer to the first opening than an intermediate portion between the first and second openings.

6. The display device according to claim 1, wherein
an edge of the second light-emitting layer overlaps the first light-emitting layer and is arranged on an inclined surface of the first opening in the insulating layer.

7. The display device according to claim 1, wherein
a second common layer is further arranged between the first and second light-emitting layers and the counter electrode.

8. The display device according to claim 1, wherein
a third pixel electrode is arranged apart from the first pixel electrode,
the insulating layer has a third opening exposing the third pixel electrode, and
the edge of the first light-emitting layer is arranged on the inclined surface of the third opening in the insulating layer.

9. The display device according to claim 8, further comprising:
a third light-emitting layer arranged between the first common layer and the counter electrode, has a lower emission start voltage than the of the first light-emitting layer and overlaps a portion of the first light-emitting layer and the third pixel electrode on the first common layer.

10. The display device according to claim 1, wherein
an emission peak wavelength of the first emission layer is 460 nm or more, 500 nm or less.

11. The display device according to claim 1, wherein
an emission peak wavelength of the first light-emitting layer is 610 nm or more, 780 nm or less.

12. The display device according to claim 8, wherein
an emission peak wavelength of the first light-emitting layer is 460 nm or more, 500 nm or less.
